(19) United States
(12) Patent Application Publication
(10) Pub. No.: US 2026/0209934 A1
(43) Pub. Date: Jul. 23, 2026

(54) DOPING CONTROL IN TMD (TRANSITION METAL DICHALCOGENIDE) FILMS

(71) Applicant: Intermolecular, Inc., San Jose, CA (US)

(72) Inventors: Sergey V. Barabash, San Jose, CA (US); Amish Chovativa, Billerica, MA (US); Michael Miller, San Jose, CA (US)

(21) Appl. No.: 19/143,855

(22) PCT Filed: Dec. 22, 2023
(86) PCT No.: PCT/US2023/085836

§ 371 Date: Jun. 26, 2025

Related U.S. Application Data
(60) Provisional application No. 63/477,532, filed on Dec. 28, 2022.

(51) Int. Cl. C23C 16/30; C23C 14/06; C23C 16/455

(52) U.S. Cl. CPC C23C 16/305; C23C 14/0623; C23C 16/45553

(57) ABSTRACT

The disclosure relates to a method of producing an intrinsic or doped transition metal dichalcogenide film comprising: providing a substrate in a deposition chamber; providing a reducing environment and an excess of chalcogen in the deposition chamber; and forming the intrinsic or doped transition metal dichalcogenide film on a surface of the substrate. The transition metal may be Mo or W, and the chalcogen may be S, Se, or Te. The reducing environment may be a hydrogen rich environment.

### RELATED APPLICATIONS

This application claims priority to U.S. Provisional Patent application No. 63/477,532 filed on Dec. 28, 2022, which is hereby incorporated by reference.

### FIELD

The disclosed and claimed subject matter relates generally to doping of TMD (Transition Metal Dichalcogenides) Films.

### BACKGROUND

MoS₂ and many other TMDs tend to natively grow n-type, and the unintended defects seem to pin the Fermi level, so that it is hard to change its position with standard doping techniques. In particular, it is notoriously hard to produce a p-doped material. Unlike in usual semiconductors, in which using <<1% of dopant atoms allows one to freely change the position of the Fermi level from nearly VBM to nearly CBM (and even to produce degenerately doped material), doping of MoS₂ seems to require much larger dopant concentrations. The usual assumption is that the persistent n-type doping is due to S vacancies which act as donors. However, reducing the number of S vacancies does not appear to clearly benefit doping control (even though it does improve the other properties of the film).

There exists a need to produce TMD films in a controlled manner such that the TMD films are doped (p-type doped) or undoped (intrinsic).

### SUMMARY

In a first aspect, the disclosed subject matter relates to a method of producing an intrinsic or doped transition metal dichalcogenide film comprising: providing a substrate in a deposition chamber; providing a reducing environment and an excess of chalcogen in the deposition chamber; and forming the intrinsic or doped transition metal dichalcogenide film on a surface of the substrate.

In a further aspect of the first aspect, the transition metal is Mo or W. In a further aspect of aspect 1, the chalcogen is S, Se, or Te. In a further aspect of aspect 1, the reducing environment is a hydrogen rich environment having a concentration of 0.1-100 Torr partial pressure of H₂ gas. In a further aspect of the first aspect, the deposition chamber comprises H₂S having a concentration of 0.1-100 Torr partial pressure of H₂S gas. In a further aspect of the first aspect, the intrinsic or doped transition metal dichalcogenide film is formed at a temperature of between about 100 and about 800° C. In a further aspect of the first aspect, the intrinsic or doped transition metal dichalcogenide film is deposited via ALD or CVD. In a further aspect of the first aspect, the intrinsic or doped transition metal dichalcogenide film is deposited via one or more physical vapor deposition (PVD) processes, including MBE, evaporation, and/or sputtering. In a further aspect of the first aspect, the intrinsic or doped transition metal dichalcogenide film is formed at a temperature of between about 150 and about 750° C.

In a second aspect, an intrinsic or doped transition metal dichalcogenide film comprising: MoS₂, MoSe₂, MoTe₂, WS₂, WSe₂, or WTe₂ formed in an environment that is formed by the method of the first aspect.

In a further aspect of the second aspect, the intrinsic or doped transition metal dichalcogenide film is grown using atomic layer deposition an (ALD) process or processes, a chemical vapor deposition process or processes, or physical vapor deposition (PVD) processes, including MBE, evaporation, and/or sputtering. In a further aspect of the second aspect, the intrinsic or doped transition metal dichalcogenide film is grown using or in the presence of excess H₂S, H₂Se, and/or H₂Te.

In a further aspect of the second aspect, the intrinsic or doped transition metal dichalcogenide film of any of the foregoing aspects, wherein H₂ gas is flowed in the process space with the chalcogenide reactant during the process whether chalcogenide reactant is a dihydro-chalcogenide, an alkyl-chalcogenide, an alkyl-dichalcogenide, and/or a chalcogenide vapor. In a further aspect of the second aspect, the intrinsic or doped transition metal dichalcogenide film comprises p-doped WS₂. In a further aspect of the second aspect, the intrinsic or doped transition metal dichalcogenide film comprises intrinsic WS₂. In a further aspect of the second aspect, the intrinsic or doped transition metal dichalcogenide film comprises p-doped MoS₂. In a further aspect of the second aspect, the intrinsic or doped transition metal dichalcogenide film comprises intrinsic MoS₂. In a further aspect of the second aspect, the intrinsic or doped transition metal dichalcogenide film of any of the foregoing aspects is intrinsic and the substrate is doped.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates the density of states of MoS₂ with neutral H_ad defects modeled using DFT, highlighting the formation energy lowering expected if the H_ad defects are introduced into an intrinsic MoS₂; and

FIG. 2 illustrates the density of states of MoS₂ with neutral OH defects modeled using DFT, highlighting the formation energy lowering expected if the H_ad defects are introduced into an intrinsic MoS₂.

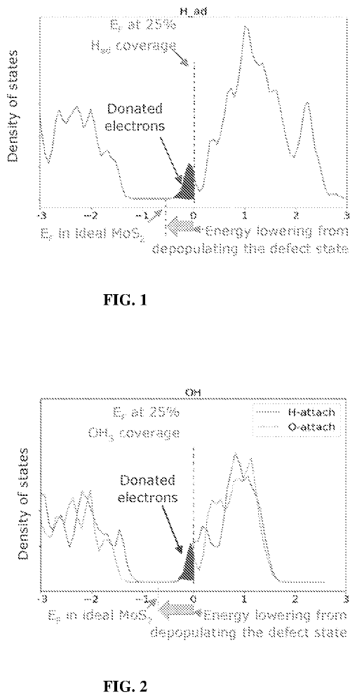

### DEFINITIONS

Unless otherwise stated, the following terms used in the specification and claims shall have the following meanings for this application.

In this application, the use of the singular includes the plural, and the words “a,” “an” and “the” mean “at least one” unless specifically stated otherwise. Furthermore, the use of the term “including,” as well as other forms such as “includes” and “included,” is not limiting. Also, terms such as “element” or “component” encompass both elements or components including one unit and elements or components that include more than one unit, unless specifically stated otherwise. As used herein, the conjunction “and” is intended to be inclusive and the conjunction “or” is not intended to be exclusive, unless otherwise indicated. For example, the phrase “or, alternatively” is intended to be exclusive. As used herein, the term “and/or” refers to any combination of the foregoing elements including using a single element.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

For purposes of this invention and the claims hereto, the numbering scheme for the Periodic Table Groups is according to the IUPAC Periodic Table of Elements.

The term “and/or” as used in a phrase such as “A and/or B” herein is intended to include “A and B,” “A or B,” “A” and “B.”

As used herein, the terms “metal-containing complex” (or more simply, “complex”) and “precursor” are used interchangeably and refer to a metal-containing molecule or compound which can be used to prepare a metal-containing film by a deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal nitride film, metal silicide film, a metal carbide film and the like.

As used herein, the terms “elemental metal,” “elemental metal film” and “pure metal film” are used interchangeably and refer to a film which consists of, or consists essentially of, pure metal. For example, an elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. However, a film comprising an elemental metal is distinguished from binary films including a metal and a non-metal (e.g., C, N, O) and ternary films including a metal and two non-metals (e.g., C, N, O), though, a film comprising elemental metal may include some amount of impurities. Unless context dictates otherwise, the term “metal film” shall be interpreted to mean an elemental metal film.

As used herein, the terms “deposition process” and “thermally depositing” are used to refer to any type of deposition technique, including but not limited to, CVD and ALD. In various embodiments, CVD may take the form of conventional (i.e., continuous flow) CVD, liquid injection CVD, plasma-enhanced CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al., J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds. The Royal Society of Chemistry: Cambridge, 2009; Chapter 1, pp 1-36.

Unless otherwise indicated, “alkyl” refers to hydrocarbon groups which can be linear, branched (e.g., methyl, ethyl, propyl, isopropyl, tert-butyl and the like), cyclic (e.g., cyclohexyl, cyclopropyl, cyclopentyl and the like) or multicyclic (e.g., norbornyl, adamantly and the like). Suitable acyclic groups can be methyl, ethyl, n- or iso-propyl, n-, iso, or tert-butyl, linear or branched pentyl, hexyl, heptyl, octyl, decyl, dodecyl, tetradecyl and hexadecyl. Unless otherwise stated, alkyl refers to 1-10 carbon atom moieties. The cyclic alkyl groups may be mono cyclic or polycyclic. Suitable examples of mono-cyclic alkyl groups include substituted cyclopentyl, cyclohexyl, and cycloheptyl groups. The substituents may be any of the acyclic alkyl groups described herein. As mentioned herein the cyclic alkyl groups may have any of the acyclic alkyl groups as substituent. These alkyl moieties may be substituted or unsubstituted.

Defect notation: explicit subscripting such as “A_{B}” (particularly in Table I) and the TeX-inspired subscript notation such as “A_B” are used interchangeably throughout the text. Such notation is standard for the one skilled in art. For the reference, the notation describes a point defect at a specific position in a crystal, listing the actual species (element, dimer, vacancy, etc.) found at that position in regular font and the species normally found at that position in an ideal crystal as a subscript, so A_B would be a substitution with A on B site. For example, Vs or V_S would be a vacancy on a S site.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

This disclosure provides that in order to control doping of TMD (such as MoS₂, WS₂, etc.) films, and particularly in order to provide p-type doping, —OH and —H defects should be eliminated. For that, the material should be grown in H₂O-free and optimally reducing conditions (slightly less reducing than H₂), in addition to maintaining S-rich conditions. As soon as both —OH and —H related defects are virtually eliminated, one would be able to easily control the position of the Fermi level by standard methods.

Control of doping may include: (1) improving the resolution of what doping level is achieved, (2) broadening the range of achievable doping, and (3) providing extra resilience in terms of how doping might be affected by small variations in deposition environment. This may include changes in the deposition/manufacturing process or variation of parameters (such as concentrations, temperature, etc.) with position on an industrial-scale wafer with multiple high-aspect features.

DFT calculations indicate that, contrary to the usual expectations, the S vacancy (V_S) does not act as a donor. While V_S does create a defect level below the CBM, the neutral defect state does not carry an electron, and can only act as an electron trap (in which case it becomes negatively charged). Other native defects, as well as oxygen O_S defect (substitution on S site) similarly lack the doping potential and only create defect states. Moreover, most defects are very high in energy; the only exception is O_S which (depending on the chemical potentials) can have a negative formation energy, and the S vacancy and S adatom, which in MoS₂ both can have a formation energy of ~1 eV.

TABLE I
Defect energies for the listed native, oxygen- and water-related defects in MoS₂.

| | | | | | | Estimated charged defect energies for | | | |
|---|---|---|---|---|---|---|---|---|---|
| | | | | | | E_{F} near mid-gap (i.e., in defect-free | | | |
| | | Neutral Defect Energies | | | | MoS₂) | | | |
| Defect | | Mo- | S- | Mo- | S- | Mo- | S- | Mo- | S- |
| type | Doping | rich | rich | rich | rich | rich | rich | rich | rich |
| V_{S} | (electron trap) | 1.3 | 2.6 | 1.3 | 2.6 | 1.3 | 2.6 | 1.3 | 2.6 |
| S_{ad} | (hole trap) | 2.4 | 1.1 | 2.4 | 1.1 | 2.4 | 1.1 | 2.4 | 1.1 |
| H_{ad} | n | 3.0 | 3.0 | 1.7 | 1.7 | 2.1 | 2.1 | 0.8 | 0.8 |
| H_{S} | (doping killer) | 2.2 | 3.5 | 0.96 | 2.3 | 2.2 | 3.5 | 0.96 | 2.3 |
| OH_{S} | n | −0.43 | 0.88 | 0.83 | 2.1 | −1.33 | −0.02 | −0.07 | 1.2 |
| O_{S} | (hole trap) | −2.6 | −0.66 | | | −2.6 | −0.66 | | |
| O2_{S} | (electron trap) | −0.30 | 1.0 | 4.7 | 6.0 | −0.30 | 1.0 | 4.7 | 6.0 |

The neutral defect energies are directly calculated from DFT simulations, the charged defect energies are estimated from the position of the defect level. The formation energies listed above in TABLE I are for the “critical” values of chemical potentials assuming high partial pressures; calculated values may be sensitive to the calculation method and the approximate density functional used and are only given to illustrate the general trends identified rather than to provide exact numerical values.

On the other hand, residual H₂O vapor is nearly unavoidable with the majority of the deposition methods, allowing for the presence of H-containing defects, and our DFT simulations indicate that two H-containing defects are both low in energy and act as donors. These are an H_ad (H adatom) and OH_S (—OH substituting on S site). The left portion of TABLE I shows the estimated formation energies that the neutral defects at H₂O rich and simultaneously either oxidizing (O₂-rich) or reducing (H₂-rich) conditions may have. Since the neutral H_ad and OH_S defects both have an electron near the CBM, a material that is not strongly n-doped (i.e., weakly n-doped, “undoped”, or p-doped) would have the Fermi level much below the position of the defect state, and the resulting charged defect would have a much lower formation energy. As exemplified by estimates given in the right portion of TABLE I for the case of the Fermi level staying in the center of the gap (as in intrinsic, defect- and dopant-free MoS₂), the formation energy of the charged OH_S defect may become negative at all except strongly reducing S-rich conditions. This means that it is absolutely necessary to maintain strongly reducing S-rich conditions in order to be able to move the position of the Fermi level away from that of the OH_S defect state. On the other hand, if the strongly reducing S-rich conditions are maintained, it should be possible to control the position of the Fermi level relatively freely, including making the material lightly or even moderately p-doped. The accuracy of the current estimates does not allow to conclusively predict whether it could be possible to achieve p+ doping under those conditions, but if it is possible those conditions would definitely need be maintained.

The H_ad defect remains relatively large energy, but at strongly reducing S-rich conditions it has even lower energy than OH_S. Since its energy does not depend on S chemical potential, maintaining S-rich conditions (thus increasing the energy of OH_S) is always optimal. However, as far as the H chemical potential goes (i.e., how strongly reducing the environment is), it can be optimized so as to have the equally high formation energies of OH_S and H_ad. The optimum would depend on the temperature and the partial pressure of H₂O, but at moderate temperature and H₂O vapor presence it should be slightly less reducing than a H₂-rich environment.

It is easier to eliminate OH_S defects in WS₂ as the have considerably higher energy (e.g., −0.35 eV) in WS₂ than in MoS₂. Thus, if the Fermi level needs be positioned at or below mid-gap (“undoped” or p-doped), WS₂ should be preferred to MoS₂.

In some embodiments, the intrinsic TMD film is on a surface having a charged imbalance. For example, the 2D material while intrinsic may be said to be “interfacially doped”, whereby the film itself is chemically pure and does not have any dopant atoms inside the film, however, a material that is in close proximity with the film (e.g., the substrate on which it is grown) has a charge imbalance near the interface that results in the film behaving as if it were doped. In such embodiments, the TMD film is intrinsic and the substrate is doped.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

In certain embodiments, a method of producing an intrinsic or doped transition metal dichalcogenide film comprising: providing a substrate in a deposition chamber; providing a reducing environment and an excess of chalcogen in the deposition chamber; providing an additional control of self-doping; and forming the intrinsic or doped transition metal dichalcogenide film on a surface of the substrate.

In certain embodiments, the transition metal is Mo or W.

In certain embodiments, the chalcogen is S, Se, or Te.

In certain embodiments, the reducing environment is a hydrogen rich environment having a concentration of 0.1-100 Torr partial pressure of H₂ gas.

In certain embodiments, the deposition chamber comprises H₂S having a concentration of 0.1-100 Torr partial pressure of H₂S gas.

In certain embodiments, the doped transition metal dichalcogenide film is formed at a temperature of about 100 to about 800° C., more preferably between about 150 and about 750° C.

In certain embodiments, the doped transition metal dichalcogenide film is deposited via ALD or CVD.

In certain embodiments, the doped transition metal dichalcogenide film is deposited via one or more physical vapor deposition (PVD) processes, including MBE, evaporation, and/or sputtering.

In certain embodiments, the intrinsic or doped transition metal dichalcogenide film comprising: MoS₂, MoSe₂, MoTe₂, WS₂, WSe₂, or WTe₂ formed in an environment that is chalcogen-rich.

In certain embodiments, the intrinsic or doped transition metal dichalcogenide film is grown using atomic layer deposition an (ALD) process or processes, a chemical vapor deposition process or processes, or physical vapor deposition (PVD) processes, including MBE, evaporation, and/or sputtering.

In certain embodiments, the film is grown using or in the presence of excess H₂S, H₂Se, and/or H₂Te.

In certain embodiments, H₂ gas is flowed in the process space with the chalcogenide reactant during the process whether chalcogenide reactant is a dihydro-chalcogenide, an alkyl-chalcogenide, an alkyl-dichalcogenide, and/or a chalcogenide vapor.

The content of H₂O should be minimized. In a preferred embodiment, the presence of water is avoided in the process, preferably by using cryopumps to efficiently evacuate the residual H₂O pressure.

Regarding the reducing environment, H₂ gas is unique among reducing species as it cannot react with the metal to form a hydride to any appreciable extent, which is different than other reducing gases such as NH₃, PH₃, B₂H₆, CH₄, SiH₄, Si₂H₆, which do form compounds with Mo and/or W to rival the desired TMD deposition.

In certain embodiments, excess H₂S, H₂Se, and/or H₂Te both supply the excess chalcogenide in the process, but also ensure a reducing environment for the reaction.

In the illustrated embodiments, the intrinsic or doped TMD films are formed via ALD. It should be noted that the intrinsic or doped TMD films of may be deposited by any suitable methods including thermal ALD, plasma-enhanced ALD (PEALD), low pressure chemical vapor deposition (LPCVD), plasma-enhanced chemical vapor deposition (PECVD), physical vapor deposition (PVD) (e.g., sputtering), or other process. In some embodiments, physical vapor deposition (PVD) processes, include molecular beam epitaxy (MBE), evaporation, and/or sputtering.

With any of these PVD processes occurring with reactive gases in the process space to ensure excess chalcogen and, simultaneously, a reducing environment.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

1. A method of producing an intrinsic or p-doped transition metal dichalcogenide film comprising:
providing a substrate in a deposition chamber;
providing a transition metal, wherein the transition metal is Mo or W;
providing a reducing environment and an excess of chalcogen in the deposition chamber; and
forming the intrinsic or p-doped transition metal dichalcogenide film on a surface of the substrate.

2. (canceled)

3. The method of claim 1, wherein the chalcogen is S, Se, or Te.

4. The method of claim 1, wherein the reducing environment is a hydrogen rich environment having a concentration of 0.1-100 Torr partial pressure of H₂ gas.

5. The method of claim 1, wherein the deposition chamber comprises H₂S having a concentration of 0.1-100 Torr partial pressure of H₂S gas.

6. The method of claim 1, wherein the intrinsic or p-doped transition metal dichalcogenide film is formed at a temperature of between about 100 and about 800° C.

7. The method of claim 1, wherein the intrinsic or p-doped transition metal dichalcogenide film is deposited via ALD or CVD.

8. The method of claim 1, wherein the intrinsic or p-doped transition metal dichalcogenide film is deposited via one or more physical vapor deposition (PVD) processes, including MBE, evaporation, and/or sputtering.

9. The method of claim 1, wherein the intrinsic or p-doped transition metal dichalcogenide film is formed at a temperature of between about 150 and about 750 degrees Celsius.

10. An intrinsic or p-doped transition metal dichalcogenide film comprising: MoS₂, MoSe₂, MoTe₂, WS₂, WSe₂, or WTe₂ formed in an environment that is formed by the method of claim 1.

11. The intrinsic or p-doped transition metal dichalcogenide film of claim 10, wherein the film is grown using atomic layer deposition an (ALD) process or processes, a chemical vapor deposition process or processes, or physical vapor deposition (PVD) processes, including MBE, evaporation, and/or sputtering.

12. The intrinsic or p-doped transition metal dichalcogenide film of claim 10, wherein the film is grown using or in the presence of excess H₂S, H₂Se, and/or H₂Te.

13. The intrinsic or p-doped transition metal dichalcogenide film of claim 10, wherein H₂ gas is flowed in the process space with the chalcogenide reactant during the process whether chalcogenide reactant is a dihydro-chalcogenide, an alkyl-chalcogenide, an alkyl-dichalcogenide, and/or a chalcogenide vapor.

14. The intrinsic or p-doped transition metal dichalcogenide film of claim 10, wherein the intrinsic or p-doped transition metal dichalcogenide film comprises p-doped WS₂.

15. The intrinsic or p-doped transition metal dichalcogenide film of claim 10, wherein the intrinsic or p-doped transition metal dichalcogenide film comprises intrinsic WS₂.

16. The intrinsic or p-doped transition metal dichalcogenide film of claim 10, wherein the intrinsic or p-doped transition metal dichalcogenide film comprises p-doped MoS₂.

17. The intrinsic or p-doped transition metal dichalcogenide film of claim 10, wherein the intrinsic or p-doped transition metal dichalcogenide film comprises intrinsic MoS₂.

18. The intrinsic or p-doped transition metal dichalcogenide film of claim 10, wherein the intrinsic or p-doped transition metal dichalcogenide film is intrinsic and the substrate is doped.
